(19) United States
(12) Patent Application Publication
(10) Pub. No.: US 2009/0087974 A1
(43) Pub. Date: Apr. 2, 2009

(54) METHOD OF FORMING HIGH-K GATE ELECTRODE STRUCTURES AFTER TRANSISTOR FABRICATION

(76) Inventors: Andrew Waite, Hopewell Junction, NY (US); Andy Wei, Dresden (DE)

Correspondence Address: WILLIAMS, MORGAN & AMERSON, 10333 RICHMOND, SUITE 1100, HOUSTON, TX, 77042, US

(21) Appl. No.: 12/163,023

(22) Filed: Jun. 27, 2008

(30) Foreign Application Priority Data
Sep. 29, 2007 (DE) 10 2007 046 849.2

(51) Int. Cl. H01L 21/28

(52) U.S. Cl. 438/592; 257/E21.19

(57) ABSTRACT

A sophisticated high-k metal gate electrode structure may be formed after the deposition of a first part of an interlayer dielectric material, thereby providing a high degree of process compatibility with conventional CMOS techniques. Thus, sophisticated strain-inducing mechanisms may be readily implemented in the overall process flow, while nevertheless avoiding any high temperature processes during the formation of the sophisticated high-k dielectric gate stack.

### BACKGROUND OF THE INVENTION

1. Field of the Invention

Generally, the present disclosure relates to the fabrication of highly sophisticated integrated circuits, including transistor elements comprising highly capacitive gate structures on the basis of a high-k gate dielectric of increased permittivity compared to conventional gate dielectrics, such as silicon dioxide and silicon nitride.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit elements that substantially determine performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor is considered, typically comprises so-called PN junctions that are formed by an interface of highly doped regions, referred to as drain and source regions, with a slightly doped or non-doped region, such as a channel region, disposed adjacent to the highly doped regions.

In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel (which depends on the conductivity of the gate electrode) and the channel resistivity substantially determine the transistor characteristics, the scaling of the channel length, and associated therewith the reduction of channel resistivity and increase of gate resistivity, is a dominant design criterion for accomplishing an increase in the operating speed of the integrated circuits.

Presently, the vast majority of integrated circuits are based on silicon due to substantially unlimited availability, the well-understood characteristics of silicon and related materials and processes and the experience gathered during the last 50 years. Therefore, silicon will likely remain the material of choice for future circuit generations designed for mass products. One reason for the dominant importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes as are required, for example, for anneal cycles to activate dopants and to cure crystal damage without sacrificing the electrical characteristics of the interface.

For the reasons pointed out above, silicon dioxide is preferably used as a gate insulation layer in field effect transistors that separates the gate electrode, frequently comprised of polysilicon or other metal-containing materials, from the silicon channel region. In steadily improving device performance of field effect transistors, the length of the channel region has been continuously decreased to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. The short channel behavior may lead to an increased leakage current and to a dependence of the threshold voltage on the channel length. Aggressively scaled transistor devices with a relatively low supply voltage and thus reduced threshold voltage may suffer from an exponential increase of the leakage current while also requiring enhanced capacitive coupling of the gate electrode to the channel region. Thus, the thickness of the silicon dioxide layer has to be correspondingly decreased to provide the required capacitance between the gate and the channel region. For example, a channel length of approximately 0.08 μm may require a gate dielectric made of silicon dioxide as thin as approximately 1.2 nm. Although generally high speed transistor elements having an extremely short channel may preferably be used for high speed applications, whereas transistor elements with a longer channel may be used for less critical applications, such as storage transistor elements, the relatively high leakage current caused by direct tunneling of charge carriers through an ultra-thin silicon dioxide gate insulation layer may reach values for an oxide thickness in the range or 1-2 nm that may not be compatible with thermal design power requirements for performance driven circuits.

Therefore, replacing silicon dioxide as the material for gate insulation layers has been considered, particularly for extremely thin silicon dioxide gate layers. Possible alternative materials include materials that exhibit a significantly higher permittivity so that a physically greater thickness of a correspondingly formed gate insulation layer provides a capacitive coupling that would be obtained by an extremely thin silicon dioxide layer. Commonly, a thickness required for achieving a specified capacitive coupling with silicon dioxide is referred to as capacitance equivalent thickness (CET). Thus, at a first glance, it appears that simply replacing the silicon dioxide with high-k materials is a straightforward way to obtain a capacitance equivalent thickness in the range of 1 nm and less.

It has thus been suggested to replace silicon dioxide with high permittivity materials such as tantalum oxide (Ta₂O₅) with a k of approximately 25, strontium titanium oxide (SrTiO₃) having a k of approximately 150, hafnium oxide (HfO₂), HfSiO, zirconium oxide (ZrO₂) and the like.

Additionally, transistor performance may be increased by providing an appropriate conductive material for the gate electrode to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides enhanced capacitance based on the same thickness as a silicon dioxide layer, while additionally maintaining leakage currents at an acceptable level. On the other hand, the non-polysilicon material, such as titanium nitride and the like, may be formed so as to connect to the high dielectric material, thereby substantially avoiding the presence of a depletion zone. Since typically a low threshold voltage of the transistor, which represents the voltage at which a conductive channel forms in the channel region, is desired to obtain the high drive currents, commonly the controllability of the respective channel requires pronounced lateral dopant profiles and dopant gradients, at least in the vicinity of the PN junctions. Therefore, so-called halo regions are usually formed by ion implantation in order to introduce a dopant species whose conductivity type corresponds to the conductivity type of the remaining channel and semiconductor region to “reinforce” the resulting PN junction dopant gradient after the formation of respective extension and deep drain and source regions. In this way, the threshold voltage of the transistor significantly determines the controllability of the channel, wherein a significant variance of the threshold voltage may be observed for reduced gate lengths. Hence, by providing an appropriate halo implantation region, the controllability of the channel may be enhanced, thereby also reducing the variance of the threshold voltage, which is also referred to as threshold roll-off, and also reducing significant variations of transistor performance with a variation in gate length. Since the threshold voltage of the transistors is significantly determined by the work function of the metal-containing gate material, an appropriate adjustment of the effective work function with respect to the conductivity type of the transistor under consideration has to be guaranteed.

After forming sophisticated gate structures including a high-k dielectric and a metal-based gate material, however, high temperature treatments may be required, which may result in a reduction of the permittivity of the gate dielectric caused by an increase of the oxygen contents in the high-k material, thereby also resulting in an increase of layer thickness. Furthermore, a shift of the work function may be observed which is believed to be associated with the enhanced oxygen affinity of many high-k dielectric materials, resulting in a redistribution of oxygen from trench isolation structures via the high-k dielectric material of shared gate line structures, in particular at the moderately high temperatures required for completing the transistors after forming the high-k metal gate structure. Due to this Fermi level shift in the metal-containing gate materials, the resulting threshold voltage may become too high to enable the use of halo implantation techniques for adjusting the transistor characteristics with respect to controlling threshold voltage roll-off to allow high drive current values at moderately low threshold voltages.

The moderate and high temperatures during the transistor fabrication process may be avoided by using an integration scheme in which the gate electrode structure is formed according to conventional techniques and is finally replaced by a sophisticated high-k metal gate structure, wherein the respective metals are appropriately selected so as to have suitable work functions for N-channel transistors and P-channel transistors, respectively. Thus, in this integration scheme, the conventional polysilicon/oxide gate structure is removed and replaced by the high-k metal stack after the final high temperature anneal processes and the silicidation of the drain and source regions. Hence, the high-k metal gate electrode structure may only experience low temperatures used in the back-end processing, that is, temperatures of approximately 400° C., thereby substantially avoiding the above-described problems with respect to altering the characteristics of the high-k material and shifting the work functions of the metals in the gate electrodes.

As previously explained, the N-channel transistors and P-channel transistors require very different metal-containing materials for appropriately adjusting the work function and thus the threshold voltage of the different transistor types. Therefore, respective integration schemes may be highly complex and may also be difficult to be combined with well-established dual overlayer stressor approaches, which are typically used for providing a highly stressed dielectric material with different intrinsic stress above the N-channel transistors and the P-channel transistors, respectively. In addition, in many cases, transistors in different device regions, such as CPU cores, peripheral regions for input/output, memory regions and the like, may be operated at different supply voltages, thereby requiring an appropriately adjusted layer thickness of the gate insulation layers, which in conventional integration strategies is accomplished by growing an increased oxide thickness as required for the highest operating voltage and selectively reducing the oxide thickness to re-grow an oxide at high performance regions operated at low supply voltages. The integration of gate dielectrics adapted to different operating voltages may be difficult to be combined with an approach for forming the high-k metal gates after completing the transistor structures, since a plurality of complex masking regimes at transistor level may be required.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to advanced semiconductor devices and methods for forming the same in which gate electrode structures may be formed on the basis of a high-k dielectric in combination with appropriate metal-containing conductive materials having appropriate work functions for P-channel transistors and N-channel transistors, respectively, wherein the gate electrode structures may be formed at a manufacturing stage after any high temperature treatments and after forming a portion of the interlayer dielectric material, thereby providing a high degree of compatibility with well-established stress-inducing mechanisms while substantially avoiding any shifts in work functions and deleterious effects on the high-k dielectric materials, as is previously described.

One illustrative method disclosed herein comprises forming a first transistor having a first gate electrode structure above a first device region and forming a first portion of a first interlayer dielectric material above the first transistor. Furthermore, the method comprises removing material of the first interlayer dielectric material to expose a top surface of the first gate electrode structure and replacing the first gate electrode structure by a first replacement gate electrode structure comprising a high-k gate dielectric material. Additionally, the method comprises forming a second interlayer dielectric material above the first replacement gate electrode structure.

Another illustrative method disclosed herein comprises forming a first interlayer dielectric material above a first transistor and a second transistor. Additionally, the method comprises selectively replacing a first gate electrode structure of the first transistor with a first replacement gate electrode structure having a gate insulation layer comprising a high-k dielectric material. The method further comprises selectively replacing a second gate electrode structure of the second transistor with a second replacement gate electrode structure having a gate insulation layer comprising a high-k dielectric material. Finally, the method comprises forming a second interlayer dielectric material above the first and second transistors.

Still a further illustrative method disclosed herein comprises forming a first transistor on the basis of a first placeholder structure and forming a first dielectric material laterally adjacent to the first transistor. Moreover, the first placeholder structure is replaced by a first gate electrode structure comprising a metal-containing gate electrode material and a gate insulation layer including a high-k dielectric material.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1s schematically illustrate cross-sectional views of a semiconductor device comprising field effect transistors with sophisticated gate electrode structures during various manufacturing stages, wherein the high-k dielectric material of the sophisticated gate electrode structures is formed after embedding the transistors in a portion of an interlayer dielectric material, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein provides enhanced techniques and devices wherein sophisticated high-k dielectric metal gate stacks may be formed after the completion of the transistor structures and the formation of a portion of an interlayer dielectric material, thereby ensuring a high degree of compatibility with well-established CMOS integration regimes. That is, integration of well-established strain-inducing mechanisms, such as the provision of strained semiconductor alloys in drain and source regions of the transistors, highly stressed dielectric materials for embedding the transistor structures and the like, may be used in combination with a sophisticated high-k dielectric gate electrode without unduly contributing to the overall process complexity. Moreover, the process sequence disclosed herein for replacing the dummy gate electrode structure by the sophisticated electrode stack may also provide superior conditions for enhancing the overall stress-inducing mechanism by enabling the deposition of a further portion of the interlayer dielectric material on the basis of a planarized surface topography.

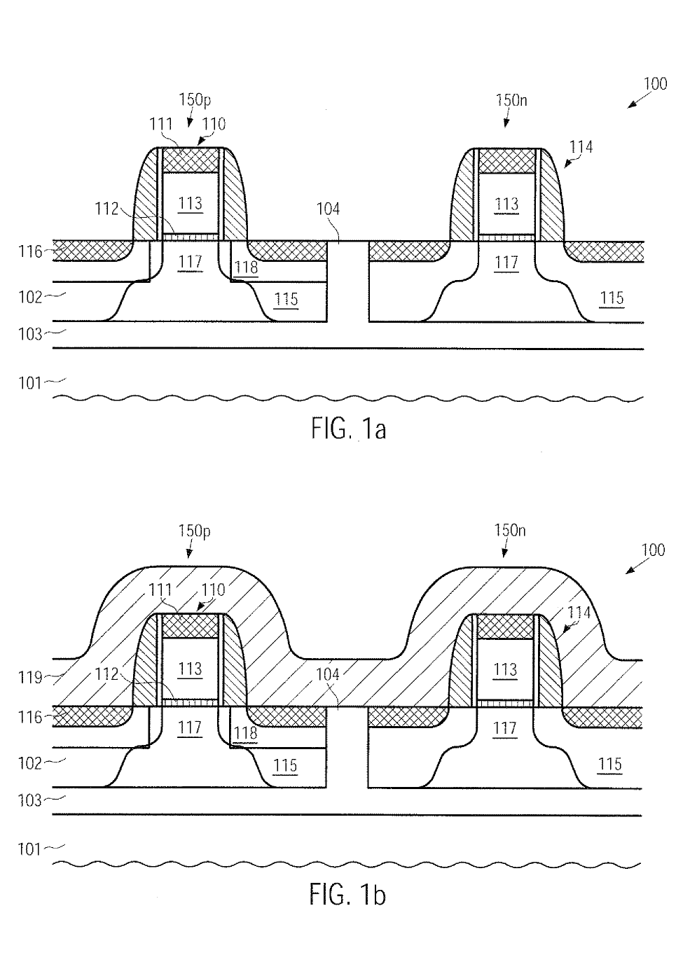

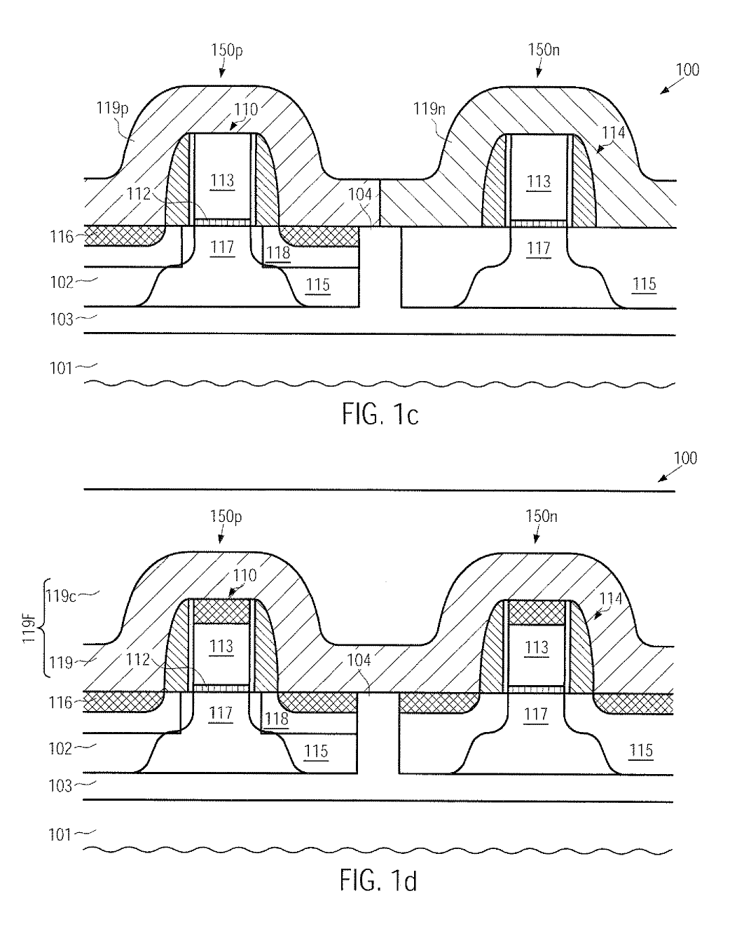

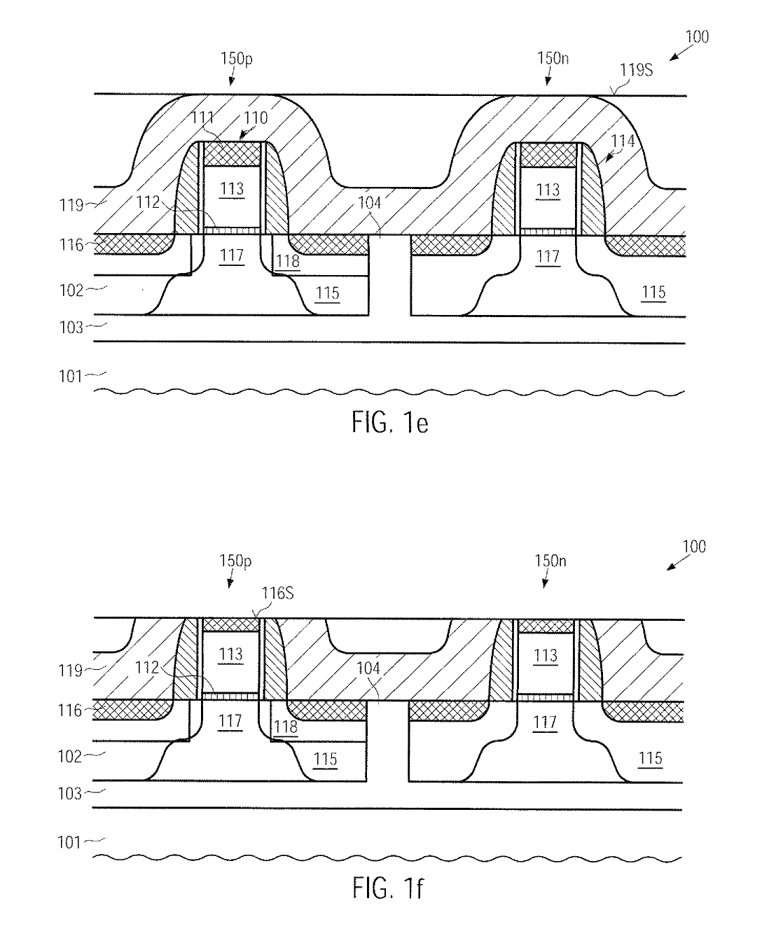

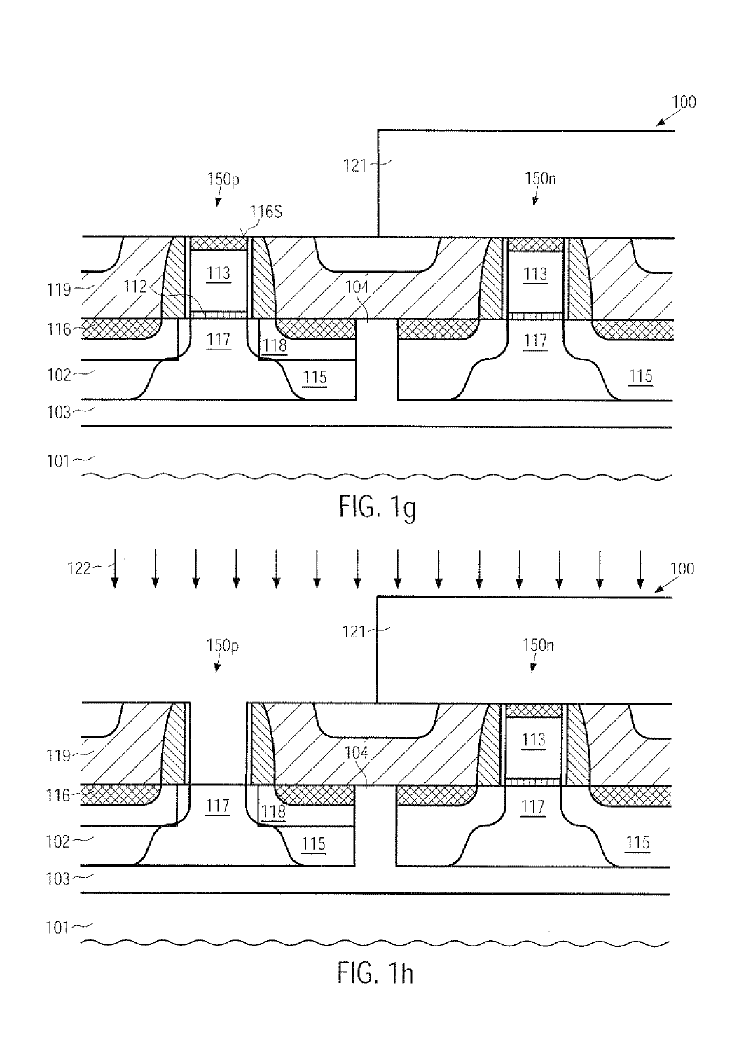

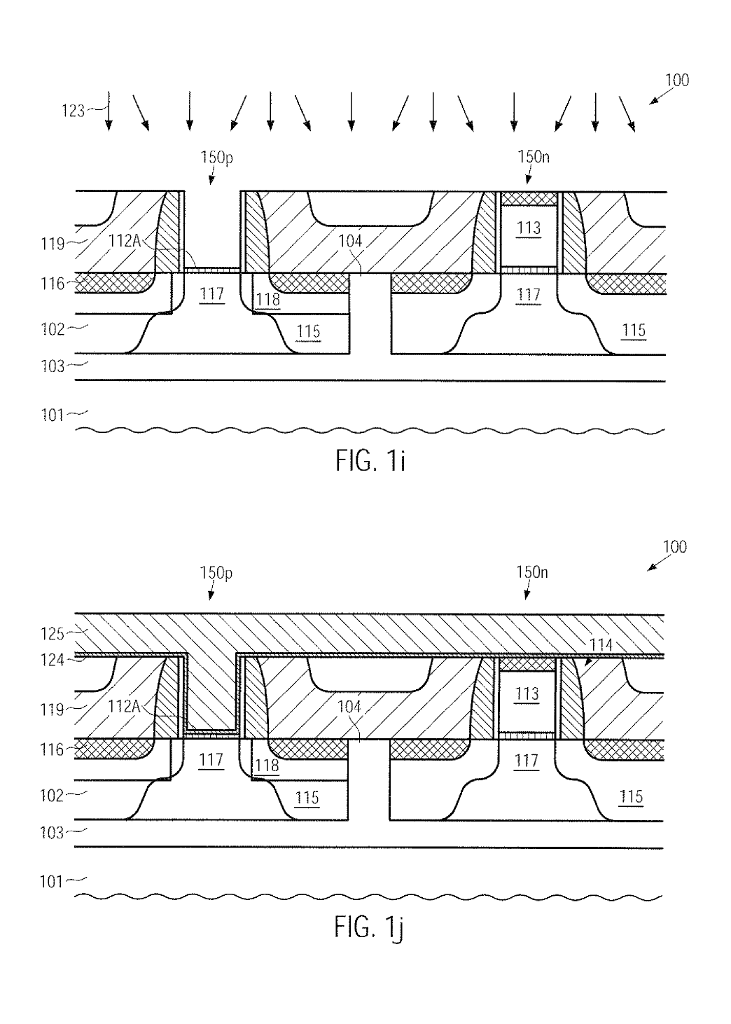

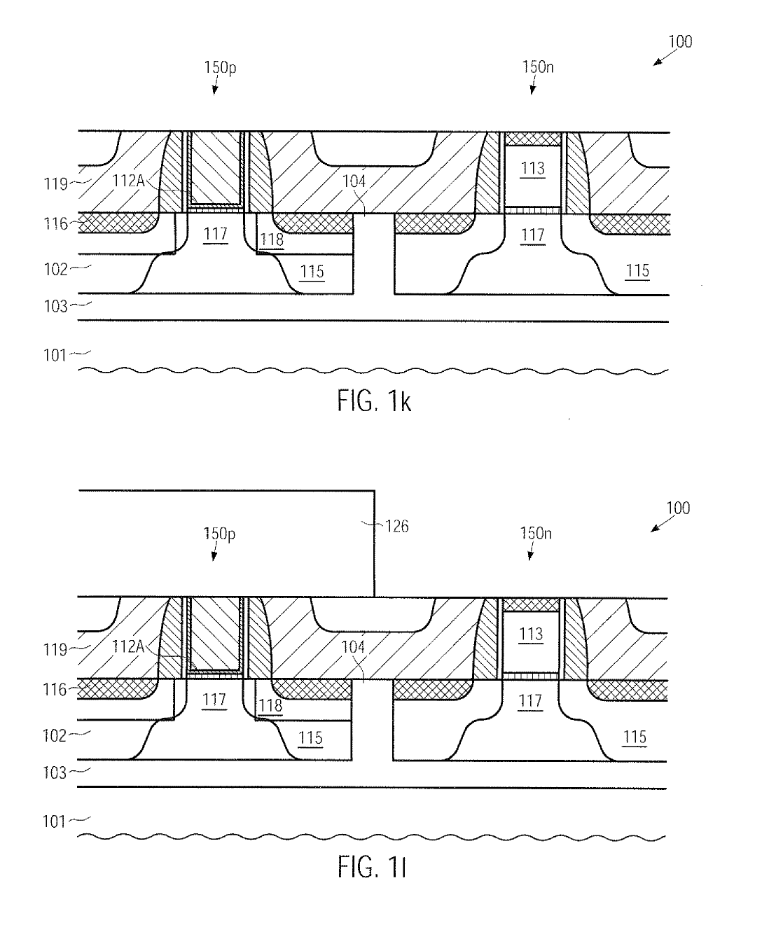

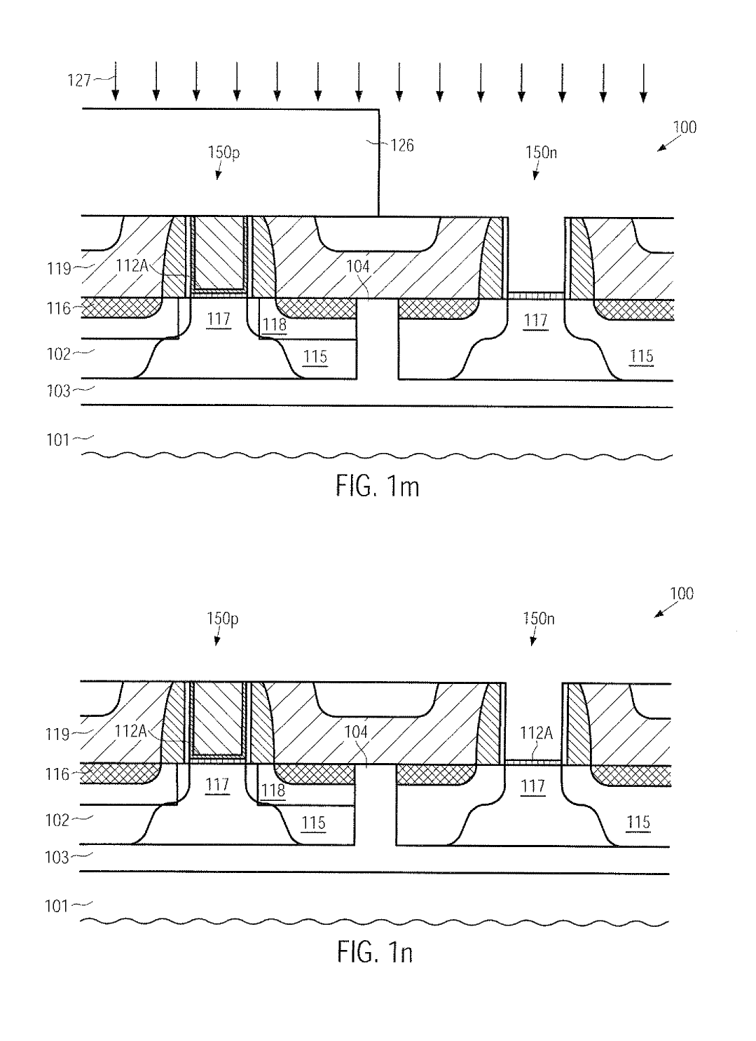

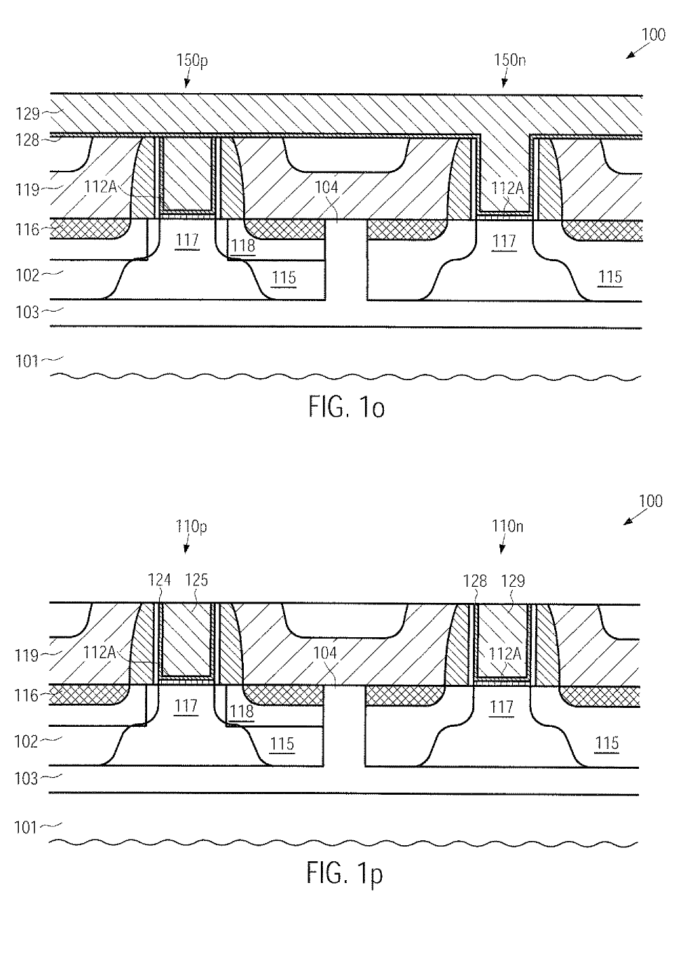

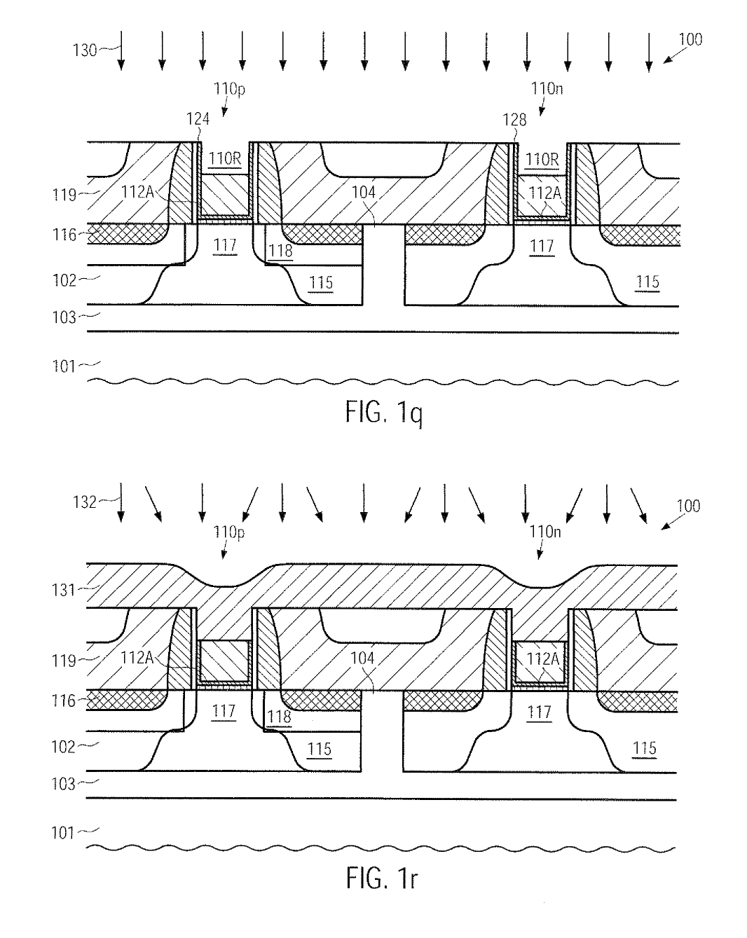

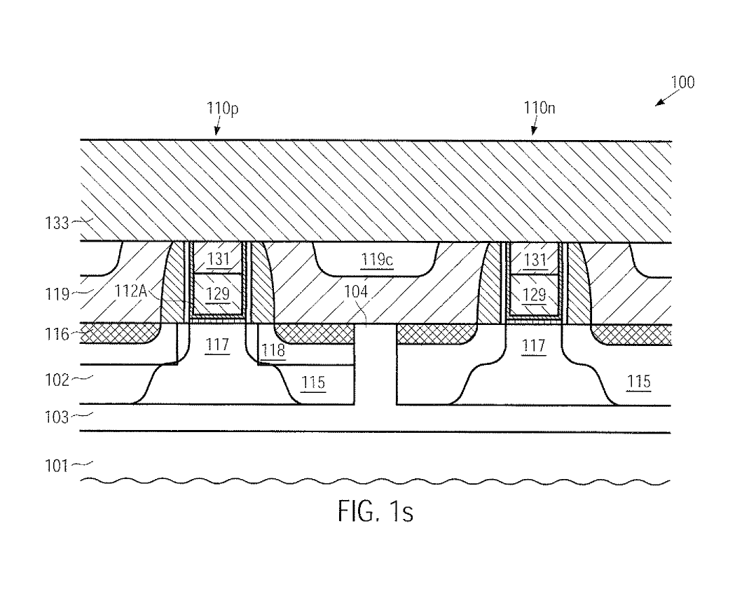

FIG. 1a schematically illustrates a cross-sectional view of a semiconductor device 100 in a manufacturing stage in which basic transistor structures have been completed, i.e., any high temperature processes have been performed so as to allow the formation of sophisticated gate electrode structures on the basis of a high-k dielectric material and appropriately selected metal-containing materials, while avoiding deleterious effects on the high-k material, as previously described. A high-k dielectric material is to be understood as a dielectric having a greater permittivity compared to silicon dioxide based materials or silicon nitride based materials. For example, a high-k dielectric material may have a dielectric constant of approximately 10 or higher. The semiconductor device 100 may comprise, in this manufacturing stage, a substrate 101, which may represent any appropriate carrier material for forming thereabove a semiconductor layer 102, such as a silicon-based layer or any other appropriate semiconductor material for forming therein and thereon transistor elements 150p, 150n, which may represent, in the embodiment shown, a P-channel transistor and an N-channel transistor, respectively. It should be appreciated that, in other embodiments, a single type of transistor may be contemplated so that the subsequent process sequence may be applied to one or more transistors of the same type. It is further to be noted that the semiconductor layer 102, even if it may be provided as a silicon-based layer, may include other materials, such as germanium, carbon and the like, in addition to any appropriate dopant species for creating the required lateral and vertical dopant profiles in the transistors 150p, 150n. For example, in the embodiment shown, the transistor 150p may comprise a semiconductor alloy 118, which may be provided in the form of any appropriate semiconductor compound so as to induce a desired type of strain in a channel region 117, which may be substantially comprised of silicon, as silicon may exhibit a significant modification of charge carrier mobility when provided in a strained state. For example, the semiconductor alloy 118, which may be a silicon/germanium alloy for a P-channel transistor, may be provided at least in a portion of respective drain and source regions 115, wherein the semiconductor alloy 118 may have a reduced lattice constant compared to its natural lattice constant, due to its strained state, thereby inducing a certain magnitude of compressive strain in the channel region 117, which may enhance the mobility of holes. It should be appreciated that other strain-inducing mechanisms may be provided in the transistors 150p, 150n, depending on the overall process strategy. That is, for silicon-based transistor devices, a silicon/carbon compound may be formed in the drain and source regions of the transistor 150n, when representing an N-channel transistor. Furthermore, any stress memorization techniques may be employed during the formation of the transistors 150p, 150n, thereby further enhancing the strain in at least one type of transistor.

It should be appreciated that the transistors 150p, 150n may be formed as bulk transistors, i.e., the semiconductor layer 102 may be formed on a substantially crystalline substrate material, while, in other cases, the semiconductor layer 102 may be formed, at least in specific device regions, on a buried insulating layer 103, thereby providing an SOI configuration. It should be appreciated, however, that an SOI configuration and a bulk configuration may be used simultaneously in different device regions of the semiconductor device 100, wherein high performance transistors may be provided in the form of SOI transistors, while other device areas, such as memory areas and the like, may be formed on the basis of a bulk configuration.

The transistors 150p, 150n may be separated from each other by an appropriate isolation structure, such as a trench isolation 104, which may extend down to a specified depth, wherein, in the embodiment shown, the isolation structure 104 may connect to the buried insulating layer 103, thereby electrically isolating the transistors 150p, 150n. Moreover, each of the transistor elements 150p, 150n may comprise a gate electrode structure 110, which may represent any appropriate structure, such as a placeholder structure substantially comprised of dielectric materials, while, in other cases, the gate electrode structures 110 may represent functional conventional gate electrode structures, for instance based on polysilicon, wherein, in some illustrative embodiments, respective gate electrode structures may be substantially maintained in other device regions (not shown), while the structures 110 of the transistors 150n, 150p may be replaced by a sophisticated gate electrode structure including a high-k dielectric material and a highly conductive metal-containing electrode material. For example, the gate electrode structure 110 may comprise a conventional gate dielectric material 112, such as a silicon dioxide based gate dielectric, above which may be formed a conventional gate electrode material 113, such as a polysilicon material and the like, followed by a metal silicide region 111. Similarly, metal silicide regions 116 may be formed in the drain and source regions 115. Furthermore, depending on the process strategy, a sidewall spacer structure 114 may be provided on sidewalls of the gate electrode structures 110. The sidewall spacer structure 114 may comprise, in this manufacturing stage, any number of individual spacer elements, depending on process and device requirements.

The semiconductor device 100 as shown in FIG. 1a may be formed on the basis of well-established process techniques. For instance, the gate electrode structures 110 may be formed on the basis of sophisticated deposition and/or oxidation techniques for forming the gate dielectric materials 112, wherein an appropriate thickness may be selected when the conventional gate dielectric material 112 is to be maintained in other device regions (not shown). Thereafter, sophisticated lithography and etch techniques may be used for forming the gate electrode material 113, for instance in the form of polysilicon and the like. In other cases, any appropriate placeholder material may be used if the gate electrode structures 110 of the entire semiconductor device have to be replaced by sophisticated high-k metal gate electrode structures. Next, the sidewall spacer structure 114 may be formed, at least partially, so as to act as an appropriate etch mask, if a semiconductor alloy 118 is to be formed within respective recesses formed on the basis of the spacer structure 114. In other cases, respective spacers for forming recesses for the semiconductor alloy 118 may be removed and a portion of the structure 114 may be subsequently provided to act as an appropriate implantation mask for creating the lateral dopant profile for the drain and source regions 115. It should be appreciated that a plurality of implantation processes may be required, such as extension implantation, halo implantation, an amorphization implantation and deep drain and source implantations, for obtaining the required complex dopant profile. As previously explained, the efficiency of a respective halo implantation depends on an appropriate work function of a gate electrode metal still to be formed when replacing the gate electrode structure 110 by the high-k dielectric metal gate stack. Furthermore, during the formation of the transistor structures 150p, 150n, one or more high temperature treatments may be required, for instance, for activating dopants and re-crystallizing implantation-induced damage and the like. Finally, the metal silicide regions 116 and 111 may be formed in a common process sequence with process parameters adapted to obtain the desired configuration of the metal silicide in the regions 116, while not requiring an adaptation of the process parameters in view of the metal silicide regions 111, since these regions will be removed in a later manufacturing stage. As previously explained, the respective process techniques may also include any process sequence for forming any desired strain-inducing mechanisms, such as providing the semi-conductor alloy 118 in a portion of the drain and source regions 115, while, in other cases, respective stress memorization techniques may be used, i.e., portions of the drain and source regions 115 may be amorphized and may be re-grown in the presence of a rigid cover layer, thereby generating a certain strain upon re-crystallizing the structure, wherein the strain may be conserved even after removal of the rigid overlayer.

FIG. 1b schematically illustrates the semiconductor device 100 in a further advanced manufacturing stage, in which a part of a first interlayer dielectric material 119 is formed above the transistors 150p, 150n. The first interlayer dielectric material 119 may be provided in the form of one or more material layers, depending on the process and device requirements. For example, the part 119 of the first interlayer dielectric layer may represent a conventional etch stop material as may be used for controlling an etch process for forming contact openings that connect to the transistors 150p, 150n through a further interlayer dielectric material that is to be formed in a later stage. For example, silicon nitride, nitrogen-enriched silicon carbide and the like may be used in combination with silicon dioxide based materials, thereby providing a high degree of etch selectivity. The part 119 of the first inter-layer dielectric material may be formed on the basis of well-established process strategies, thereby providing a high degree of compatibility with conventional techniques. It should be appreciated that, in some illustrative embodiments, the material 119 may be provided with a high degree of internal stress so as to induce a certain type of strain in one or both of the transistors 150p, 150n.

FIG. 1c schematically illustrates a semiconductor device 100 according to illustrative embodiments wherein the part 119 of the interlayer dielectric material may be provided in the form of different portions 119p, 119n which are designed to provide different strain conditions in the transistors 150p, 150n, respectively. For example, the portion 119p may be provided in the form of silicon nitride, nitrogen-enriched silicon carbide and the like, so as to exhibit a high internal compressive stress, thereby further enhancing a respective strain in the channel region 117 for increasing the hole mobility. Similarly, the portion 119n may exhibit a different type of internal stress or at least a significantly reduced amount of internal stress compared to the portion 119p. For example, the portion 119n may be provided in the form of a silicon nitride material or a nitrogen-enriched silicon carbide material with a substantially neutral stress behavior. In other cases, the portion 119n may be provided in the form of silicon nitride having a high tensile stress so as to induce a respective strain in the channel region 117 of the transistor 150n to enhance electron mobility therein.

The material 119 as shown in FIG. 1c may be formed on the basis of the following processes. In some illustrative embodiments, a highly stressed dielectric material, such as silicon nitride, nitrogen-enriched silicon carbide and the like, may be deposited on the basis of appropriately selected process parameters, for which well-established recipes may be used. For example, the material 119 may be deposited with high compressive stress, which may be in the range of 2-3 GPa or even higher, wherein a thickness of the layer 119 may be selected in accordance with the device geometry. That is, the gap fill capabilities of the associated deposition process may possibly limit the amount of stressed material of the layer 119. Thereafter, a portion of the layer 119 may be exposed to an ion bombardment in order to significantly relax the internal stress, thereby, for instance, forming the portion 119n. It should be appreciated that the material 119 may be deposited with high internal stress selected to enhance the characteristics of the transistor 150n and the subsequent relaxation treatment may result in a substantially stress-neutral portion 119p. In other illustrative embodiments, both portions 119p, 119n may be provided with high internal stress of different type. To this end, a dielectric material of a first internal stress may be deposited and may be subsequently removed from above one of the transistors 150n, 150p followed by the deposition of a further dielectric material having a different type of internal stress selected so as to enhance performance of the previously exposed transistor. Thereafter, excess material of this highly stressed layer may be removed from above the other transistor on the basis of appropriate etch techniques. It should be appreciated that forming the highly stressed portions 119p, 119n according to this process strategy may involve the deposition of any appropriate etch stop materials or etch indicator material, depending on the process strategy.

FIG. 1d schematically illustrates the semiconductor device 100 in a further advanced manufacturing stage wherein a second part of the first interlayer dielectric material, indicated as 119c, may be formed above the transistors 150p, 150n. In one illustrative embodiment, the second part 119c, which may be referred to, together with the previously deposited part 119, as the first interlayer dielectric material 119F, may be provided in one illustrative embodiment on the basis of a deposition technique providing the desired gap filling capabilities to provide a substantially void-free configuration of the first interlayer dielectric material 119F. For example, the second part 119c may be provided in the form of silicon dioxide, which may be deposited by sub-atmospheric chemical vapor deposition (SACVD) or high density plasma enhanced chemical vapor deposition (PECVD) on the basis of TEOS according to well-established process recipes. In other cases, the second part 119c may be provided in the form of highly stressed dielectric material so as to enhance the performance of one of the transistors 150p, 150n, as previously explained with reference to the portions 119p, 119n. For example, if the portion 119p has previously been provided as a substantial stress-neutral material, while the portion 119n provides a high internal stress for enhancing the characteristics of the transistor 150n, the material 119c may be provided with high internal stress to create strain in the transistor 150p. In other illustrative embodiments, the material 119c may be provided with substantially the same material composition as the layer 119, however with process parameters selected to enhance the gap filling capabilities rather than providing high internal stress.

FIG. 1e schematically illustrates the semiconductor device 100 during a process sequence for planarizing the surface topography and finally exposing an upper portion of the gate electrode structures 110. For example, in the manufacturing stage shown in FIG. 1e, material of the part 119c may have been removed on the basis of well-established chemical mechanical polishing (CMP) techniques, wherein appropriate selective recipes may be used when the part 119c is comprised of a different material compared to the layer part 119. For instance, highly selective CMP recipes are available for silicon dioxide and silicon nitride. In other cases, the materials of the parts 119c and 119 may have substantially the same composition and a corresponding CMP process may be continued so as to finally expose the metal silicide regions 111. In other cases, as shown in FIG. 1e, the respective CMP process may be stopped upon exposing a surface 119S of the layer part 119 and thereafter a further process, for instance in the form of a non-selective CMP process, an etch process and the like, may be performed.

FIG. 1f schematically illustrates the semiconductor device 100 after the completion of the above-described process sequence. For example, a highly non-selective plasma-based etch process may have been used to finally expose a top surface 116S of the gate electrode structures, i.e., of the metal silicide regions 111.

FIG. 1g schematically illustrates the semiconductor device 100 having formed thereon an appropriate etch mask 121 to protect one of the transistors 150p, 150n during a subsequent selective etch process for removing material of the gate electrode structures 110. In the embodiment shown in FIG. 1h, the etch mask 121, which may be provided in the form of a resist mask and the like, may cover the transistor 150n and may also cover any other device features of the semiconductor device 100 for which at least a portion of the originally formed gate electrode structures is to maintained. For example, in other device areas, the previously formed gate insulation layer 112 may have an appropriate thickness and configuration and thus at least a portion of the respective gate electrode material 113, the gate insulation layer 112 may be maintained.

FIG. 1h schematically illustrates the semiconductor device 100 during a selective etch process 122 to selectively remove the gate electrode material 113 including the remaining metal silicide 111 of the transistor 150p. For example, if the gate electrode material 113 is substantially comprised of polysilicon, well-established plasma-based recipes may be used, for instance, on the basis of hydrogen bromide (HBr) to selectively etch silicon material in the presence of the spacer structure 114 and the residue of the first interlayer dielectric material 119.

In other illustrative embodiments, the etch process 122 may be established on the basis of an appropriate wet chemical recipe, which may provide the desired degree of etch selectivity with respect to the materials of the spacer structure 114 and the interlayer dielectric material 119. For instance, a solution including TMAH (tetra methyl ammonium hydroxide) may be used, wherein TMAH is the basis of a photolithography developer material, which also etches silicon when provided in higher concentrations and at higher temperatures. On the other hand, silicon dioxide and silicon nitride are highly resistant to this solution.

Furthermore, the etch process 122 may comprise an etch stop for removing the conventional gate insulation material 112, for instance on the basis of hydrofluoric acid and the like. Prior to or after this additional etch step for removing the gate insulation layer 112, the etch mask 121 may be removed.

FIG. 1i schematically illustrates the semiconductor device 100 after the above-described process sequence. In some illustrative embodiments, the device 100 as shown in FIG. 1i may be subjected to a treatment 123 to form a thin dielectric material 112A above the channel region 117, when a direct contact of a high-k dielectric material, still to be formed, with the material of the channel region 117 may be considered inappropriate, since many high-k dielectric materials may result in a mobility degradation when being in direct contact with a silicon-based material. For example, the dielectric material 112A may be provided in the form of an oxide, which, however, may be provided with a significantly reduced thickness compared to the conventional dielectric material 112. For instance, the thickness of the layer 112A may range from approximately 4-6 Å. In other cases, any other appropriate dielectric material, such as silicon nitride and the like, may be formed. The treatment 123 may comprise any appropriate process, such as a wet chemical oxidation process, to provide the layer 112A, if required, in a highly controllable manner. In other cases, the treatment 123 may comprise a process for incorporating a desired species, such as nitrogen, oxygen and the like, on the basis of a plasma-assisted process in order to form the layer 112A with the desired thickness.

FIG. 1j schematically illustrates the semiconductor device 100 in a further advanced manufacturing stage, in which a high-k dielectric material and a metal-containing conductive material may be provided to replace the conventional gate electrode structure 110. As shown, a layer 124 of high-k dielectric material, which may represent one of the materials as mentioned above, may be formed with an appropriate thickness, which may range from approximately 15-25 Å in sophisticated applications, within the recess obtained by removing the conventional gate electrode structure 110. Furthermore, an appropriate metal-containing conductive material layer 125 may be formed to fill the previously formed recess, wherein, as previously explained, the metal-containing material 125 may have an appropriate work function as required for establishing a desired low threshold voltage for the transistor 150p. For example, titanium nitride, tantalum nitride and the like may be used as appropriate materials for the layer 125, wherein appropriately selected alloy-forming species may be incorporated so as to suitably adjust the work function of the layer 125.

The high-k dielectric material 124 may be deposited, for instance, on the basis of sophisticated atomic layer deposition (ALD) techniques in which, for instance, a self-limiting process may be performed to provide layer after layer, wherein each sub-layer has a well-defined thickness, thereby obtaining the finally desired overall thickness of the layer 124. Next, the metal-containing material of the layer 125 may be deposited, for instance, by physical vapor deposition (PVD), chemical vapor deposition (CVD), electrochemical deposition techniques and the like, depending on the type of metal used. For instance, tantalum nitride or titanium nitride based materials may be deposited on the basis of well-established PVD recipes.

FIG. 1k schematically illustrates the semiconductor device 100 after the removal of any excess material of the layers 124 and 125. For this purpose, a CMP process may be performed wherein the interlayer dielectric material 119 may act as a stop layer. In some illustrative embodiments, a substantially non-selective CMP step may follow to further enhance surface planarity, while also reliably removing any metal residues or adjusting the desired height of the gate electrode structures.

FIG. 1l schematically illustrates the semiconductor device 100 with a further etch mask 126, such as a resist mask, in order to cover the transistor 150p while exposing the transistor 150n. As previously explained with reference to the etch mask 121, the mask 126 may also cover any device features of the semiconductor device 100 which are to be protected during a subsequent selective etch process for removing the gate electrode structure 110 of the transistor 150n. Hence, by appropriately designing the etch mask 126, the conventional gate electrode structures 110 in specific device regions may be protected and may therefore be maintained, if considered appropriate for the operational behavior of these devices under consideration.

FIG. 1m schematically illustrates the semiconductor device 100 during a selective etch process 127, which may be designed to selectively remove the gate electrode material 113 of the structure 110. For example, similar process recipes may be used as previously described with respect to the etch process 123. In other cases, if the etch process 127 provides sufficient etch selectivity with respect to the material 125 (FIG. 1j), the etch mask 126 may be omitted, thereby reducing process complexity. As explained above, the etch process 127 may comprise an etch step for removing the conventional gate dielectric material 112 on the basis of any appropriate recipe. In some illustrative embodiments, a surface treatment may be performed, similar to the treatment 123 previously described, to form a thin dielectric material on the exposed channel region 117 of the transistor 150n. This may be accomplished by a plasma treatment, as previously explained, or by any appropriate wet chemical treatment, wherein the etch mask 126 may also protect the material 125 in the transistor 150p. In other cases, the etch mask 126 may be removed prior to forming a respective thin dielectric material, when the dielectric material may be attacked by a corresponding etch process for removing the etch mask 126.

Fig. 1n schematically illustrates the semiconductor device 100, with the etch mask 126 removed, when the etch mask is required for the etch process 127, and with a thin dielectric material 112A formed above the channel region 117 of the transistor 150n. As previously indicated, the layer 112A may also be formed with the transistor 150p exposed, which may, for instance, be accomplished on the basis of ozone-containing water, which may not substantially attack the metal-containing material 125 while oxidizing the exposed surface of the channel region 117.

FIG. 1o schematically illustrates the semiconductor device 100 after the deposition of a high-k dielectric material 128, which may be the same material as the material 124 (FIG. 1j) or which may represent a different material, depending on the process strategy. Furthermore, a metal-containing conductive material layer 129 is formed on the high-k dielectric layer 128 so as to fill the recess above the channel region 117 of the transistor 150n. With respect to any process techniques for forming the layers 128, 129, it may be referred to the respective process strategies explained with reference to the layers 124 and 125. It should be appreciated, however, that the metal-containing layer 129 is appropriately formed so as to exhibit a work function that is adapted to the conductivity type of the transistor 150n.

FIG. 1p schematically illustrates the semiconductor device 100 after the removal of any excess material of the layers 128 and 129, which may be accomplished on the basis of CMP, etch processes and the like, as is also previously described with reference to the layers 124 and 125. Thus, the semiconductor device 100 comprises a first replacement gate electrode structure 110p, comprising the high-k dielectric material 124 and the metal-containing material 125, possibly in combination with the dielectric layer 112A, and a second replacement gate electrode structure 110n comprising the high-k dielectric material 128 and the metal-containing material 129, possibly in combination with the dielectric layer 112A. Based on the configuration as shown in FIG. 1p, the further processing may be continued by providing a second interlayer dielectric material, thereby completing the device level of the semiconductor device 100.

It should be appreciated that, typically, gate electrodes of different types of transistors may be connected to each other above respective isolation structures (not shown) according to certain circuit designs to be able to control the gate electrodes of P-channel transistors and N-channel transistors on the basis of a single voltage signal. In this case, one or both of the high-k dielectric materials 124 and 128 may still be present between the respective metal portions 125 and 129 at these specific device areas, which may therefore electrically isolate respective combined gate electrode portions. In this case, in some illustrative embodiments, a portion of the replacement electrode structures 110p, 110n may be removed and may be refilled with any appropriate conductive material to also establish an electrical connection within gate electrode structures which extend from a P-channel transistor area into an N-channel transistor area.

FIG. 1q schematically illustrates the semiconductor device 100 during a respective selective etch process 130 to form recesses 110R in the gate electrode structures 110p, 110n. For this purpose, any appropriate wet chemical etch recipe or plasma-based etch recipe may be used that may etch the metal-containing material of the layers 125, 129 with moderately high selectivity to the first interlayer dielectric material 119 and/or the spacer structure 114. During the etch process 130, exposed portions of the layers 124 and 128 may also be removed, depending on the characteristics of the etch process 130. During the etch process 130, any thin barriers formed of the material of the layers 124 and 128 located between abutting gate electrode portions (not shown) may also be reliably removed, thereby enabling the formation of combined gate electrode lines connecting transistors of different conductivity type.

FIG. 1r schematically illustrates the semiconductor device 100 during a deposition process 132 for forming a further conductive material 131, for instance, any appropriate metal-containing material, above the transistors 150p, 150n, thereby filling the recesses 110R. Similarly, the layer 131 may provide a conductive connection between abutting gate electrode portions (not shown) in device areas above isolation structures separating transistors of different conductivity type. Next, the excess material of the layer 131 may be removed, for instance, on the basis of CMP, as previously explained with reference to the layers 125 and 129, so as to reliably provide the electrically isolated replacement gate electrode structures 110p, 110n, while providing a desired connection between abutting gate electrode portions in other device areas.

FIG. 1s schematically illustrates the semiconductor device 100 in a further advanced manufacturing stage. As shown, the replacement gate electrode structures 110p, 110n may comprise the conductive material 131, if required, and may be covered in this manufacturing stage by a second dielectric material 133, which may be provided in the form of conventional dielectric materials, such as silicon dioxide. In other illustrative embodiments, the second interlayer dielectric material 133 may be provided as a highly stressed material to further enhance the strain-inducing mechanisms, at least in one of the transistors 150p, 150n. As previously explained, the provision of a sufficient amount of highly stressed material adjacent to the transistors 150p, 150n may suffer from appropriate gap fill capabilities of the respective deposition processes. Due to the preceding process sequence, the first interlayer dielectric material 119 may be provided with enhanced surface topography, wherein possibly any gaps between adjacent transistors may be filled with appropriate techniques, such as sub-atmospheric chemical vapor deposition (SACVD) and the like by depositing the material 119C, so that the second interlayer dielectric material 133 may be provided under significantly enhanced process conditions, thereby enabling the deposition of a highly stressed material without being restricted by any gap filling capabilities. Thus, in some illustrative embodiments, a highly stressed material may be provided which may be appropriately relaxed over one type of transistor, for instance, on the basis of ion implantation techniques. In other cases, any appropriate deposition regime may be used to provide layer portions of different types of stress above the corresponding transistors 150p, 150n, wherein the enhanced surface topography of the first dielectric material 119 enables an efficient and reliable patterning regime. Thereafter, any other appropriate interlayer dielectric material may be formed, such as silicon dioxide and the like, according to well-established process strategies.

As a result, the subject matter disclosed herein provides a technique for forming transistor elements having sophisticated high-k dielectric gate insulation layers in combination with highly conductive metal-containing electrode materials with appropriately selected work functions for different types of transistors. Since a conventionally designed gate electrode stack or any appropriate placeholder structure may be maintained until a first part of an interlayer dielectric material is formed laterally adjacent to the transistor elements, a high degree of process compatibility may be maintained, thereby allowing the integration of any type of strain-inducing mechanism, such as stress memorization techniques, strained semi-conductor materials and the like. Furthermore, stressed interlayer dielectric materials may be provided in a highly efficient manner, wherein the enhanced surface topography obtained during the selective replacement of the conventional gate electrode stacks may even further enhance the overall process sequence.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first transistor having a first gate electrode structure above a semiconductor layer;
forming a first interlayer dielectric material above said first transistor;
removing material of said first interlayer dielectric material to expose a top surface of said first gate electrode structure;
replacing said first gate electrode structure by a first replacement gate electrode structure comprising a high-k gate dielectric material; and
forming a second interlayer dielectric material above said first replacement gate electrode structure.

2. The method of claim 1, wherein said first interlayer dielectric material is formed to have a high internal stress so as to induce a strain in a channel region of said first transistor.

3. The method of claim 1, wherein forming said first interlayer dielectric material comprises depositing a first material layer and a second material layer, said first and second material layers having different material compositions.

4. The method of claim 3, further comprising planarizing a surface topography of at least said first interlayer dielectric material prior to replacing said first gate electrode structure.

5. The method of claim 4, wherein forming said first replacement gate electrode structure comprises forming a first gate insulation layer comprising a high-k material, depositing a first metal-containing conductive material above said high-k dielectric material and removing excess material of said first gate insulation layer and said first metal-containing conductive material.

6. The method of claim 1, wherein material of said first gate electrode structure is removed by a selective dry etch process.

7. The method of claim 1, wherein material of said first gate electrode structure is removed by a selective wet etch process.

8. The method of claim 1, further comprising:
forming a second transistor having a second gate electrode structure above said semiconductor layer;
forming said first interlayer dielectric material above said second transistor;
removing material of said first interlayer dielectric material to expose a top surface of said second gate electrode structure;
replacing said second gate electrode structure by a second replacement gate electrode structure comprising a high-k gate dielectric material and a second metal-containing conductive material; and
forming said second interlayer dielectric material above said second replacement gate electrode structure.

9. The method of claim 8, further comprising selectively removing material of said first and second replacement gate electrode structures to form recesses therein and refilling said recesses with a third metal-containing material.

10. The method of claim 8, wherein said first replacement gate electrode structure comprises a first metal-containing conductive material having a first work function and said second metal-containing conductive material has a second work function differing from said first work function.

11. The method of claim 8, wherein forming said second portion of said first inter-layer dielectric material comprises depositing a stressed material above said second device region, said stressed material having a high internal stress so as to induce a strain in a channel region of said second transistor.

12. The method of claim 8, wherein said second interlayer dielectric material is formed above said first device region with a first internal stress and above said second device region with a second internal stress that differs from said first internal stress.

13. The method of claim 5, wherein forming said gate insulation layer comprises forming a first dielectric layer and forming a second dielectric layer comprised of said high-k dielectric layer.

14. A method, comprising:
forming a first interlayer dielectric material above a first transistor and a second transistor;
selectively replacing a first gate electrode structure of said first transistor with a first replacement gate electrode structure having a gate insulation layer comprising a high-k dielectric material;
selectively replacing a second gate electrode structure of said second transistor with a second replacement gate electrode structure having a gate insulation layer comprising a high-k dielectric material; and
forming a second interlayer dielectric material above said first and second transistors.

15. The method of claim 14, wherein forming said first interlayer dielectric material comprises forming a first portion of said first interlayer dielectric material with a first type of internal stress above said first transistor and forming a second portion above said second transistor.

16. The method of claim 14, further comprising planarizing a surface topography by removing material of said first interlayer dielectric material prior to selectively replacing said first and second gate electrode structures.

17. The method of claim 14, wherein forming said second interlayer dielectric material comprises forming a stressed material above at least one of said first and second transistors.

18. The method of claim 17, further comprising forming a first portion of said stressed material with a first type of internal stress above said first transistor and a second portion of said stressed material with a second type of internal stress above said second transistor.

19. The method of claim 14, further comprising a first recess in said first replacement gate electrode structure and a second recess in said second replacement gate electrode structure and filling said first and second recesses with a conductive material.

20. The method of claim 14, wherein selectively replacing said gate electrode structure comprises forming a first dielectric layer on an exposed surface portion after removing said gate electrode structure and forming a second dielectric layer comprised of said high-k dielectric material.

21. A method, comprising:
forming a first transistor on the basis of a first placeholder structure;
forming a first dielectric material laterally adjacent to said first transistor; and
replacing said first placeholder structure with a first gate electrode structure comprising a metal-containing gate electrode material and a gate insulation layer including a high-k dielectric material.

22. The method of claim 21, further comprising forming a second dielectric material above said first dielectric material, said first and second dielectric materials forming an interlayer dielectric material for said first transistor.

23. The method of claim 22, further comprising forming a recess in said first gate electrode structure and filling said recess with a conductive material prior to forming said second dielectric material.
